(19) United States
(12) Patent Application Publication
(10) Pub. No.: US 2017/0084819 A1
(43) Pub. Date: Mar. 23, 2017

(54) MAGNETRESISTIVE RANDOM-ACCESS MEMORY AND FABRICATION METHOD THEREOF

(71) Applicant: QUALCOMM Incorporated, San Diego, CA (US)

(72) Inventors: Yu LU, San Diego, CA (US); Wei-Chuan CHEN, Taipei (TW); Seung Hyuk KANG, San Diego, CA (US)

(21) Appl. No.: 14/859,278

(22) Filed: Sep. 19, 2015

(51) Int. Cl. H01L 43/02; H01L 43/12; H01L 43/08

(52) U.S. Cl. CPC H01L 43/02; H01L 43/08; H01L 43/12

(57) ABSTRACT

Provided are exemplary circuits including a magnetoresistive random-access memory (MRAM) and methods for fabricating the circuits. In an example, a circuit includes an MRAM. The circuit includes a bottom interconnect in a bottom interconnect level. The bottom interconnect is configured to route a signal outside of a magnetic tunnel junction (MTJ) stack. The circuit includes the MTJ stack formed on a bottom electrode at least partially embedded in the bottom interconnect level. Optionally, the circuit also includes an encapsulation layer encapsulating at least a portion of the MTJ stack. The encapsulation layer is also an electromigration cap for a second bottom interconnect in the bottom interconnect level. The second bottom interconnect is a not part of the MTJ stack. Optionally, the bottom electrode is self-aligned with the bottom interconnect.

### INTRODUCTION

This disclosure relates generally to electronics, and more specifically, but not exclusively, to methods and apparatuses relating to a circuit including a magnetoresistive random-access memory (MRAM).

Random access memory (RAM) is a ubiquitous component of modern digital architectures. RAM can be a standalone device, or can be integrated in a device that uses the RAM, such as a microprocessor, microcontroller, application-specific integrated circuit (ASIC), system-on-chip (SoC), and other like devices. RAM can be volatile or non-volatile. Volatile RAM loses its stored information whenever power is removed. Non-volatile RAM can maintain its memory contents even when power is removed. Although non-volatile RAM has advantages, such as an ability to retain its contents without applied power, conventional non-volatile RAM has slower read/write times than volatile RAM.

MRAM is a type of RAM. MRAM is a non-volatile memory technology having response (e.g., read/write) times comparable to volatile memory. In contrast to conventional RAM technologies which store data as electric charges or current flows, MRAM uses magnetic elements. As illustrated in FIGS. 1A and 1B, an in-plane magnetic tunnel junction (MTJ) storage element 100 (also known as an “MTJ stack”) can be formed from two magnetic layers, a pin layer 102 (also known as a “fixed layer”) and a free layer 106, each of which can retain a magnetic moment or polarization, and are separated by an insulating layer 104 (also known as a “tunnel barrier layer”). One of the two magnetic layers (e.g., a fixed layer or a pin layer 102), is fixed or pinned to a particular polarity. The other magnetic layer's polarity 108 (e.g., a polarity of the free layer 106) is free to change to switch magnetic moment polarity orientation. The free layer 106 can be switched by a field or a current by spin torque. A change in the polarity 108 of the free layer 106 changes the resistance of the MTJ storage element 100. For example, when the polarities are aligned, as depicted in FIG. 1A, a low resistance state exists. When the polarities are reverse-aligned, as depicted in FIG. 1B, a high resistance state exists. The polarization of the free layer 106 can be reversed by applying current in a specific direction such that the polarity of the pin layer 102 and the free layer 106 are either substantially aligned or opposite. Thus, the resistance of the electrical path through the MTJ changes depending on the alignment of the polarizations of the pin layer 102 and the free layer 106. The illustration of the MTJ storage element 100 is simplified, and each layer illustrated can comprise one or more layers of materials. There is also a perpendicular MTJ (pMTJ), in which magnetic moment polarity is vertically aligned or reverse aligned to fix a layer moment. The pMTJ also can be switched by a field or a current to provide a high resistance state (reverse aligned) or a low resistance state (aligned).

MRAM has several desirable characteristics such as high speed, high density (i.e., small bitcell size), low power consumption, and no degradation over time. Thus, MRAM is a candidate for a universal memory.

A variation of MRAM is Spin Transfer Torque Magnetoresistive Random Access Memory (STT-MRAM). STT-MRAM uses electrons that become spin-polarized as the electrons pass through a thin film (spin filter). STT-MRAM is also known as Spin Transfer Torque RAM (STT-RAM), Spin Torque Transfer Magnetization Switching RAM (Spin-RAM), and Spin Momentum Transfer RAM (SMT-RAM). During a write operation, the spin-polarized electrons exert torque on a free layer. The torque switches a polarity of the free layer. During a read operation, a current detects the resistance/logic state of the STT-MRAM.

As semiconductor feature sizes decrease, a dense pitch interconnect level can involve scaling by height. This causes a problem with integrating MTJs, as typical planarization tolerances should be met when scaling the height of the MTJ. Further, fabricating an MRAM bitcell with a reduced size also requires multiple patterning steps, such as to fabricate an MTJ's bottom electrode structure. The multiple patterning steps add significant fabrication costs and fabrication complexity. Further, fabricating with required multiple patterns also increases, or at least does not reduce, fabrication speed.

Accordingly, there are these and other previously unaddressed and long-felt industry needs for methods and apparatus that improve upon conventional methods and apparatus, including the provided improved methods and improved apparatus.

### SUMMARY

This summary provides a basic understanding of some aspects of the present teachings. This summary is not exhaustive in detail, and is neither intended to identify all critical features, nor intended to limit the scope of the claims.

Provided are exemplary circuits including a magnetoresistive random-access memory (MRAM) and methods for fabricating the circuits. In an example, provided is a circuit including an MRAM. The MRAM includes a first bottom interconnect in a bottom interconnect level. The bottom interconnect is configured to route a signal outside of a magnetic tunnel junction (MTJ) stack. The MRAM also includes a bottom electrode at least partially embedded in the bottom interconnect level. The MTJ stack is formed on the bottom electrode. The circuit can also include a top electrode coupled to the MTJ stack, and a top copper interconnect coupled to the top electrode. The circuit can also include an encapsulation layer encapsulating at least a portion of the MTJ stack. The encapsulation layer is also an electromigration cap for a second bottom interconnect in the bottom interconnect level. The second bottom interconnect is not a part of the MTJ stack. The circuit can also include an encapsulation layer encapsulating at least a portion of the MTJ stack. The encapsulation layer is also an electromigration cap for a second bottom interconnect in the bottom interconnect level. The second bottom interconnect is not coupled to the MTJ stack. Optionally, the bottom electrode is self-aligned with the bottom interconnect. Optionally, the MRAM is a spin-transfer torque-MRAM. Optionally, the bottom electrode is completely embedded in the bottom interconnect level. The circuit can also include an electronic device. The MTJ stack is a constituent part of the electronic device. The circuit can also include a mobile device, a base station, a terminal, a set top box, a music player, a video player, an entertainment unit, a navigation device, a communications device, a personal digital assistant, a fixed location data unit, a computer, or a combination thereof, with which the MTJ stack is a constituent part.

At least a part of the apparatus can be integrated on a semiconductor die. In a further example, provided is a non-transitory computer-readable medium, comprising lithographic device-executable instructions stored thereon configured to cause a lithographic device to fabricate at least a part of the apparatus.

In a further example, provided is a method for fabricating a circuit. The method includes forming an MRAM, including forming a first bottom interconnect in a bottom interconnect level. The first bottom interconnect is configured to route a signal outside of an MTJ stack. Forming the MRAM can also include forming a bottom electrode at least partially embedded in the bottom interconnect level, as well as forming the MTJ stack on the bottom electrode. The method can also include forming a top electrode coupled to the MTJ stack, and forming a top copper interconnect coupled to the top electrode. The method can also include forming an encapsulation layer encapsulating at least a portion of the MTJ stack. The encapsulation layer is also an electromigration cap for a second bottom interconnect in the bottom interconnect level. The second bottom interconnect is not a part of the MTJ stack. The method can also include forming an encapsulation layer encapsulating at least a portion of the MTJ stack. The encapsulation layer is also an electromigration cap for a second bottom interconnect in the bottom interconnect level. The second bottom interconnect is not coupled to the MTJ stack. The method can also include forming the bottom electrode as self-aligned with the bottom interconnect. The method can also include forming the MRAM as a spin-transfer torque-MRAM. The method can also include forming the bottom electrode as completely embedded in the bottom interconnect level. The method can also include integrating the MTJ stack into an electronic device. The method can also include integrating the MTJ stack into a mobile device, a base station, a terminal, a set top box, a music player, a video player, an entertainment unit, a navigation device, a communications device, a personal digital assistant, a fixed location data unit, a computer, or a combination thereof.

In another example, an exemplary circuit and methods for fabricating the circuit are provided. The circuit includes an MRAM. The MRAM includes an MTJ stack, as well as an encapsulation layer encapsulating at least a portion of the MTJ stack. The encapsulation layer is an electromigration cap for a first interconnect. The first interconnect is not a part of the MTJ stack. In an example, the encapsulation layer is an electromigration cap for a second interconnect. The second interconnect is not coupled to the MTJ stack. In another example, the circuit can also include an electronic device. The MTJ stack is a constituent part of the electronic device. In another example, the circuit includes a mobile device, a base station, a terminal, a set top box, a music player, a video player, an entertainment unit, a navigation device, a communications device, a personal digital assistant, a fixed location data unit, a computer, or a combination thereof, of which the MTJ stack is a constituent part.

At least a part of the apparatus can be integrated on a semiconductor die. In a further example, provided is a non-transitory computer-readable medium, comprising lithographic device-executable instructions stored thereon configured to cause a lithographic device to fabricate at least a part of the apparatus.

In a further example, provided is a method for fabricating a circuit. The method includes forming an MRAM. Forming the MRAM includes forming an MTJ stack, as well as forming an encapsulation layer encapsulating at least a portion of the MTJ stack. The encapsulation layer is an electromigration cap for a first interconnect. The first interconnect is not a part of the MTJ stack. The method can further include forming the encapsulation layer as an electromigration cap for a second interconnect. The second interconnect is not coupled to the MTJ stack. Optionally, the method can further include integrating the MTJ stack into an electronic device. The method can further include integrating the MTJ stack into a mobile device, a base station, a terminal, a set top box, a music player, a video player, an entertainment unit, a navigation device, a communications device, a personal digital assistant, a fixed location data unit, a computer, or a combination thereof.

The foregoing broadly outlines some of the features and technical advantages of the present teachings so the detailed description and drawings can be better understood. Additional features and advantages are also described in the detailed description. The conception and disclosed examples can be used as a basis for modifying or designing other devices for carrying out the same purposes of the present teachings. Such equivalent constructions do not depart from the technology of the teachings as set forth in the claims. The inventive features are characteristic of the teachings, and together with further objects and advantages, are better understood from the detailed description and the accompanying drawings. Each of the drawings is provided for the purpose of illustration and description only, and does not limit the present teachings.

### BRIEF DESCRIPTION OF THE DRAWINGS

The accompanying drawings are presented to describe examples of the present teachings, and are not limiting.

FIGS. 1A and 1B depict a magnetic tunnel junction (MTJ) storage element.

FIG. 2 depicts another MTJ storage element and other circuitry.

FIGS. 3A-3K depict exemplary methods for fabricating an exemplary MTJ structure and other circuitry.

FIG. 4 depicts an exemplary wireless communication network.

FIG. 5 depicts a functional block diagram of an exemplary user device.

FIG. 6 depicts functional block diagrams of an exemplary access point and an exemplary computer.

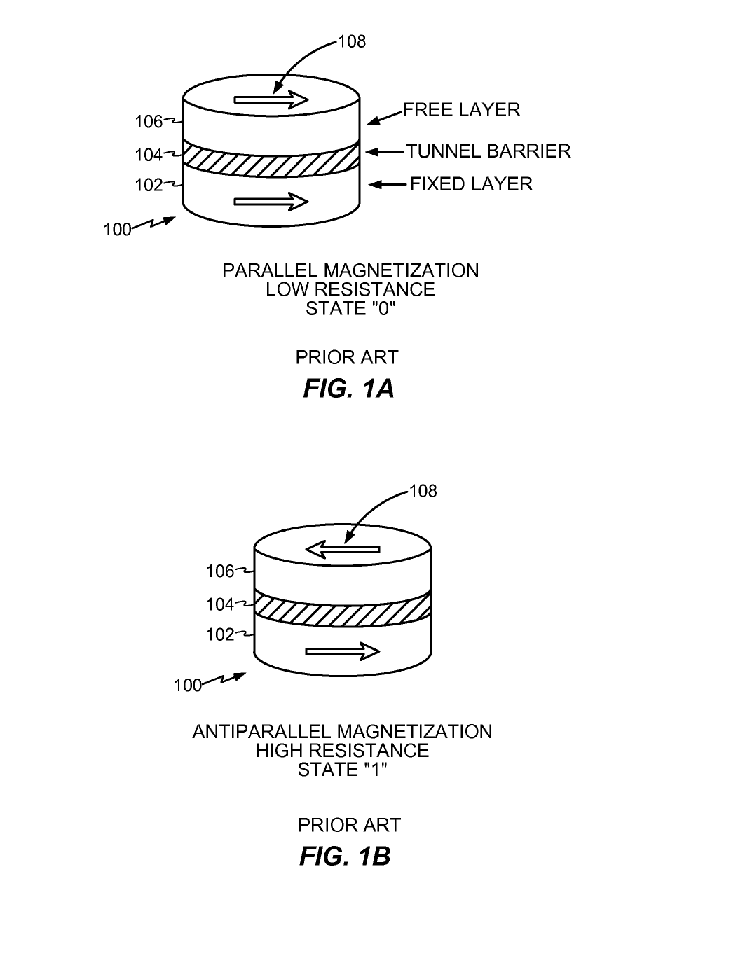

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

### Introduction

Provided are exemplary circuits including a magnetoresistive random-access memory (MRAM) and methods for fabricating the circuits.

The exemplary apparatuses and exemplary methods disclosed herein advantageously address at least one of the long-felt industry needs, as well as other previously unidentified needs, and mitigates shortcomings of conventional methods and conventional apparatus. Among other advantages, an exemplary advantage provided by at least one example of the disclosed apparatuses and/or at least one example of the methods disclosed herein is an improvement, over conventional devices, in ease of scaling down a circuit to a smaller feature size. Further, an exemplary advantage provided by at least one example of the disclosed apparatuses and/or at least one example of the methods disclosed herein is an improvement, over conventional devices, in ease of meeting planarization tolerances when scaling a height of a magnetic tunnel junction (MTJ). Moreover, an exemplary advantage provided by at least one example of the disclosed apparatuses and/or at least one example of the methods disclosed herein is an improvement, over conventional devices, in a reduction in a number of patterns required to fabricate an MTJ (such as a number of patterns required to fabricate the MTJ's bottom electrode structure). Also, an exemplary advantage provided by at least one example of the disclosed apparatuses and/or at least one example of the methods disclosed herein is a reduction in fabrication speed, a reduction in fabrication costs, or a combination thereof.

Examples are disclosed in this application's text and drawings. Alternate examples can be devised without departing from the scope of the disclosure. Additionally, conventional elements of the current teachings may not be described in detail, or may be omitted, to avoid obscuring aspects of the current teachings.

### Abbreviations

The following exemplary list of abbreviations, acronyms, and terms is provided to assist in comprehending the current disclosure, and are not provided as limitations.
AP—Access point
ASIC—Application-specific integrated circuit
AT—Access terminal
BE—Bottom electrode
BL—Bit line
CMP—Chemical-mechanical planarization
Co—Cobalt
Cu—Copper
DD—Dual-damascene
DL—Downlink
EM—Electromigration
ESL—Etch stop layer
FL—Free layer
HM—Hardmask
MHM—Metal hardmask
MRAM—Magnetoresistive random-access memory
MTJ—Magnetic tunnel junction
Mx—Metal layer “x”
NVRAM—Non-volatile random access memory
PID—Plasma-induced-damage
PL—Pin layer
PR—Photoresist
RAM—Random-access memory
ROM—Read-only memory
Ru—Ruthenium
SiN—Silicon nitride
SoC—system-on-chip
STT—Spin-transfer torque
STT-MRAM—Spin-transfer torque magnetoresistive random-access memory
Ta—Tantalum
TaN—Tantalum Nitride
TE—Top electrode
UE—User Equipment
UL—Uplink
ULK—Ultra-low K

As used herein, the term “exemplary” means “serving as an example, instance, or illustration.” Any example described as “exemplary” is not necessarily to be construed as preferred or advantageous over other examples. Likewise, the term “examples” does not require all examples to include the discussed feature, advantage, or mode of operation. Use of the terms “in one example,” “an example,” “in one feature,” and/or “a feature” in this specification does not necessarily refer to the same feature and/or example. Furthermore, a particular feature and/or structure can be combined with one or more other features and/or structures. Moreover, at least a portion of the apparatus described hereby can be configured to perform at least a portion of a method described hereby.

The terms “connected,” “coupled,” and any variant thereof, mean any connection or coupling between elements, either direct or indirect, and can encompass a presence of an intermediate element between two elements that are “connected” or “coupled” together via the intermediate element. Coupling and connection between the elements can be physical, logical, or a combination thereof. Elements can be “connected” or “coupled” together, for example, by using one or more wires, cables, printed electrical connections, electromagnetic energy, and the like. The electromagnetic energy can have a wavelength at a radio frequency, a microwave frequency, a visible optical frequency, an invisible optical frequency, and the like, as practicable. These are several non-limiting and non-exhaustive examples.

The term “signal” can include any signal such as a data signal, an audio signal, a video signal, a multimedia signal, an analog signal, a digital signal, and the like. Information and signals described herein can be represented using any of a variety of different technologies and techniques. For example, data, an instruction, a process step, a process block, a command, information, a signal, a bit, a symbol, and the like that are references herein can be represented by a voltage, a current, an electromagnetic wave, a magnetic field, a magnetic particle, an optical field, an optical particle, and/or any practical combination thereof, depending at least in part on the particular application, at least in part on the desired design, at least in part on the corresponding technology, and/or at least in part on like factors.

A reference using a designation such as “first,” “second,” and so forth does not limit either the quantity or the order of those elements. Rather, these designations are used as a convenient method of distinguishing between two or more elements or instances of an element. Thus, a reference to first and second elements does not mean that only two elements can be employed, or that the first element must necessarily precede the second element. Also, unless stated otherwise, a set of elements can comprise one or more elements. In addition, terminology of the form “at least one of: A, B, or C” or “one or more of A, B, or C” or “at least one of the group consisting of A, B, and C” used in the description or the claims can be interpreted as “A or B or C or any combination of these elements.” For example, this terminology can include A, or B, or C, or A and B, or A and C, or A and B and C, or 2A, or 2B, or 2C, and so on.

The terminology used herein is for the purpose of describing particular examples only and is not intended to be limiting. As used herein, the singular forms “a,” “an,” and “the” include the plural forms as well, unless the context clearly indicates otherwise. In other words, the singular portends the plural, where practicable. Further, the terms “comprises,” “comprising,” “includes,” and “including,” specify a presence of a feature, an integer, a step, a block, an operation, an element, a component, and the like, but do not necessarily preclude a presence or an addition of another feature, integer, step, block, operation, element, component, and the like.

In at least one example, the provided apparatuses can be at least a part of an electronic device, coupled to the electronic device, or a combination thereof, where the electronic device can be, but is not limited to, a mobile device, a navigation device (e.g., a global positioning system receiver, a global navigation satellite system receiver, etc.), a wireless device, a camera, an audio player, a camcorder, a computer, a game console, the like, or a combination thereof.

The term “mobile device” can describe, and is not limited to: a mobile phone, a mobile communication device, a pager, a personal digital assistant, a personal information manager, a personal data assistant, a mobile hand-held computer, a portable computer, a tablet computer, a wireless device, a wireless modem, an other type of portable electronic device typically carried by a person and having communication capabilities (e.g., wireless, cellular, infrared, short-range radio, etc.), the like, or a combination thereof. Further, the terms “user equipment” (UE), “mobile terminal,” “user device,” “mobile device,” and “wireless device” can be interchangeable.

Spatial descriptions (e.g., “top,” “middle,” “bottom,” “left,” “center,” “right,” “up,” “down,” “vertical,” “horizontal,” etc.) used herein are for illustrative purposes only, and are not limiting descriptors. Practical implementations of the structures described hereby can be spatially arranged in any orientation providing the functions described hereby.

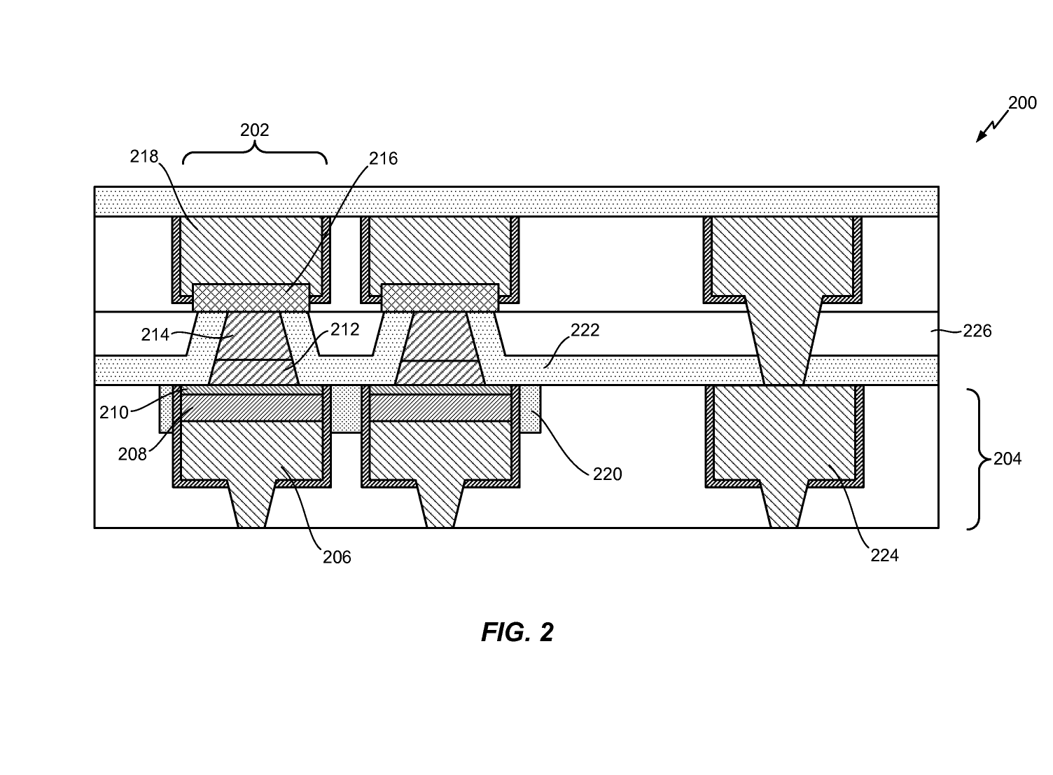

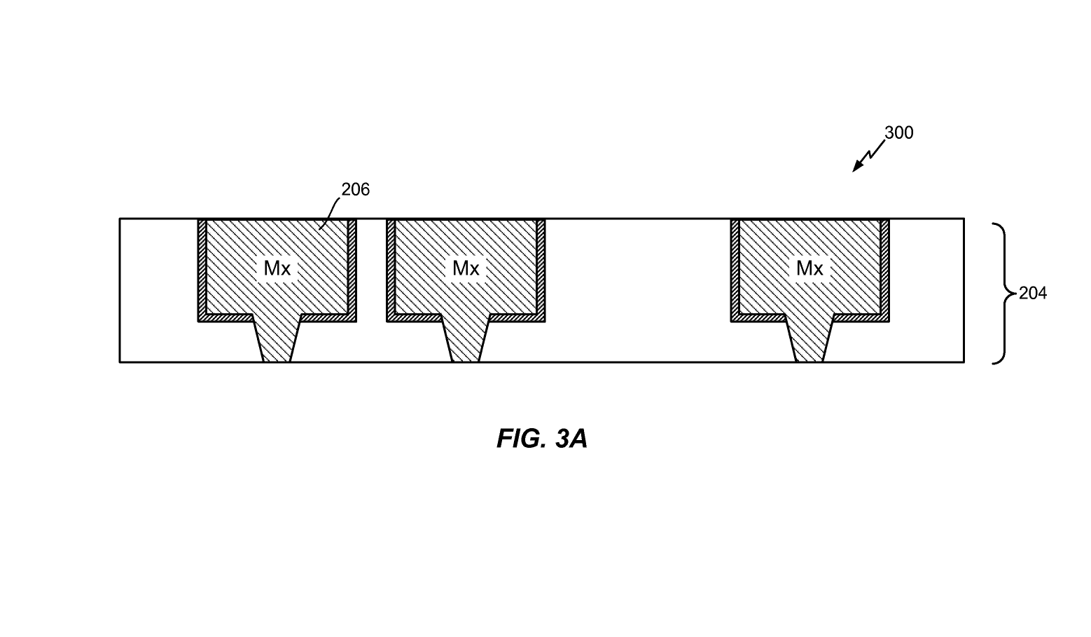

FIG. 2 depicts a circuit 200 that includes an exemplary memory cell 202. The circuit 200 is formed on a substrate that includes a bottom interconnect level 204. The bottom interconnect level 204 provides a metal layer (e.g., a copper layer) that can include vias, metal lines, and other electrically conductive structures that electrically connect integrated devices (e.g., the memory cell 202) that are formed on the substrate.

The memory cell 202 includes a first bottom interconnect 206 located in the bottom interconnect level 204. The first bottom interconnect 206 is formed of an electrically-conductive material, such as Ag, Al, Bi, Cu, In, Mo, Ni, Pb, Sn, Ta, Ti, W, polysilicon, or a combination thereof.

A bottom electrode (BE) 208 of the memory cell 202 is located at least in part in the bottom interconnect level 204, and can be electrically coupled to the first bottom interconnect 206. The BE 208 can be formed of at least one of Ta or Ru. The BE 208 can be formed as a structure that self-aligns with the first bottom interconnect 206. The BE 208 can be formed at least partially embedded in the bottom interconnect level 204. In an example, the BE 208 can be formed completely within the bottom interconnect level 204 (i.e., the BE 208 does not extend beyond the perimeter of the bottom interconnect level 204).

A base layer metal 210 is located on the BE 208. The base metal layer 210 electrically couples the BE 208 to a MTJ stack 212. The base layer metal 210 is formed of an electrically-conductive material, such as TaN. The base layer metal 210 can have a physical property that enables an electromigration (EM) issue.

Electromigration is a movement and redistribution of material, such as metal in an interconnect (e.g., a metal line, a via, etc.) caused by momentum transfer between conducting electrons and diffusing atoms in the metal. Electromigration can cause the interconnect to completely fracture (e.g., form a void) and thus provide an electrical “open.” Further, EM can also cause the interconnect to become thin and thus provide an unintended region of high electrical resistance. Additionally, EM can cause a bridge (e.g., a whisker, a hillock formation) between the interconnect and another electrical conductor (e.g., another interconnect), and thus provide an electrical “short.” As semiconductor feature size decreases, interconnect dimensions decrease, and thus the effects of EM increase. Encapsulating the interconnect can limit movement and redistribution of material. Thus, encapsulating can mitigate EM and the effects thereof. In some cases encapsulating can eliminate EM and the effects thereof.

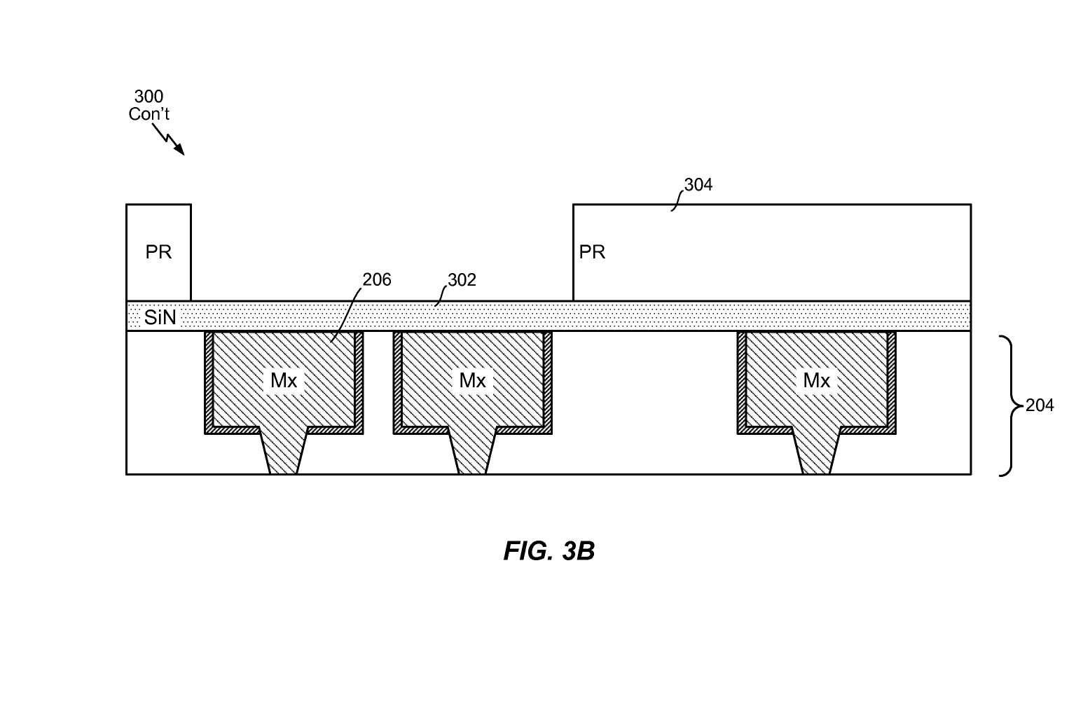

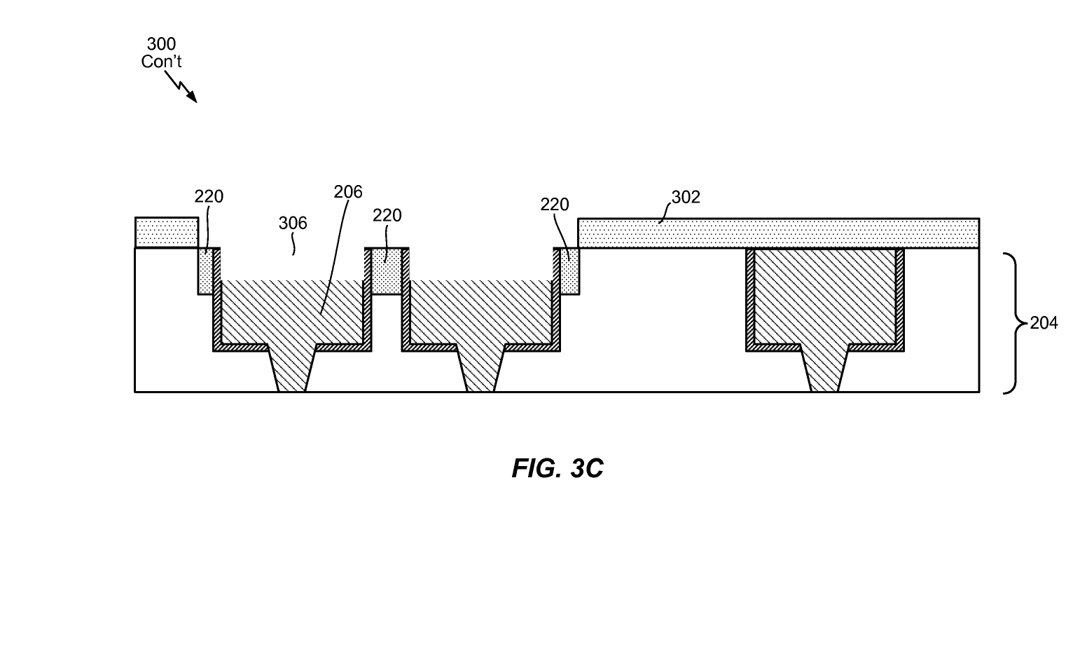

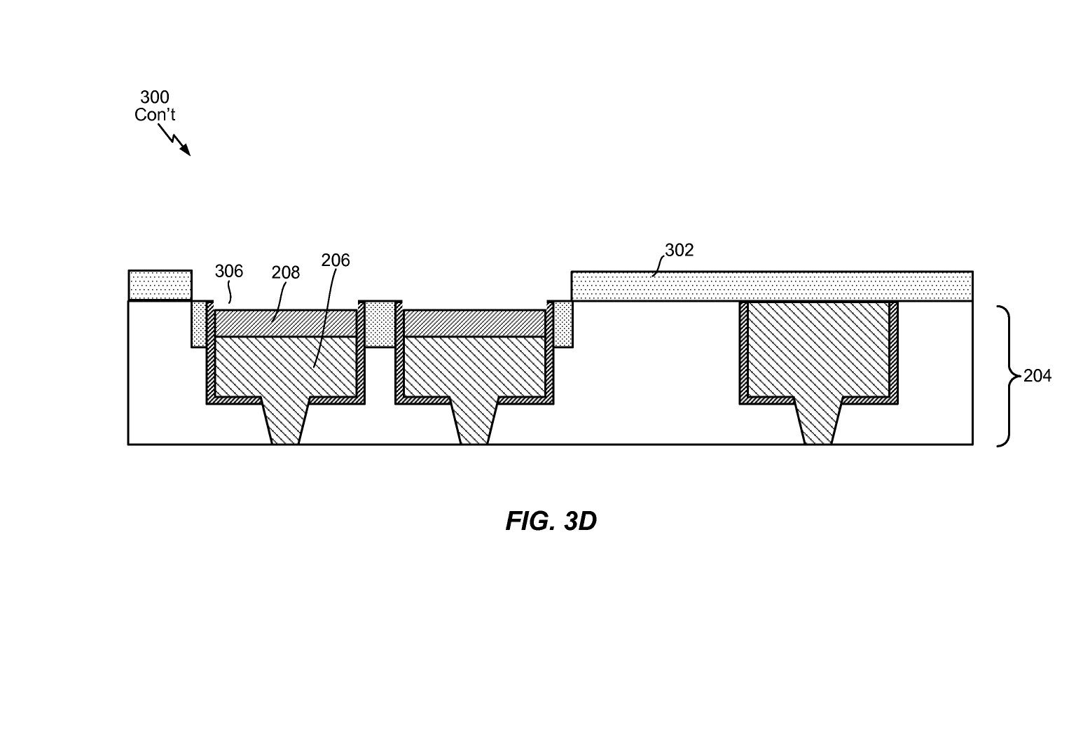

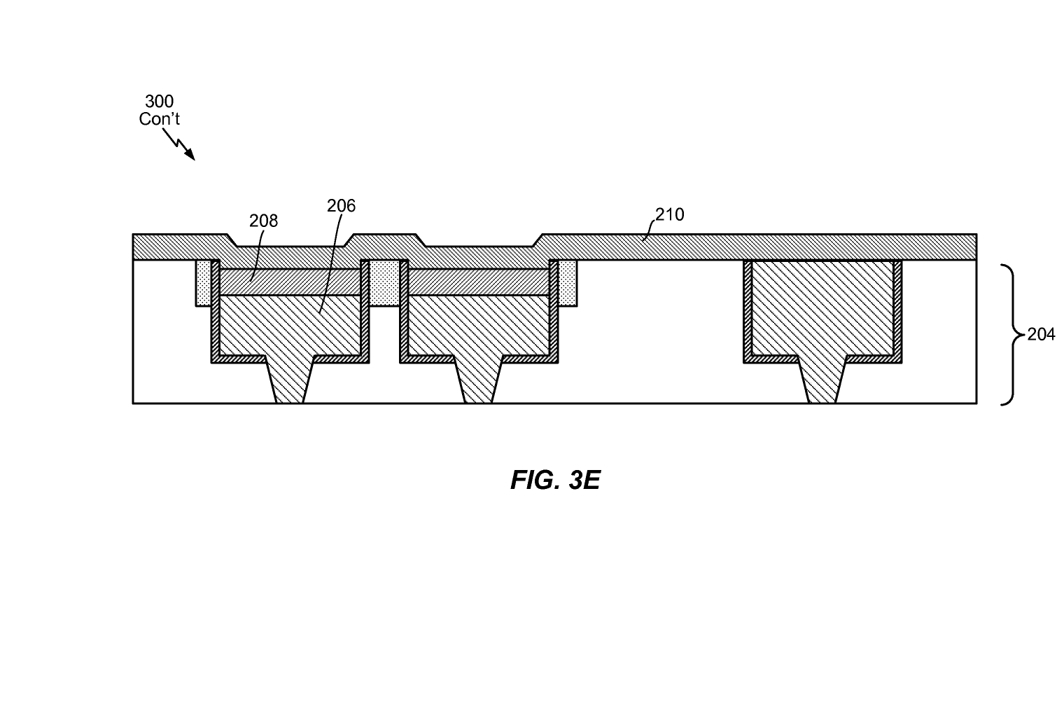

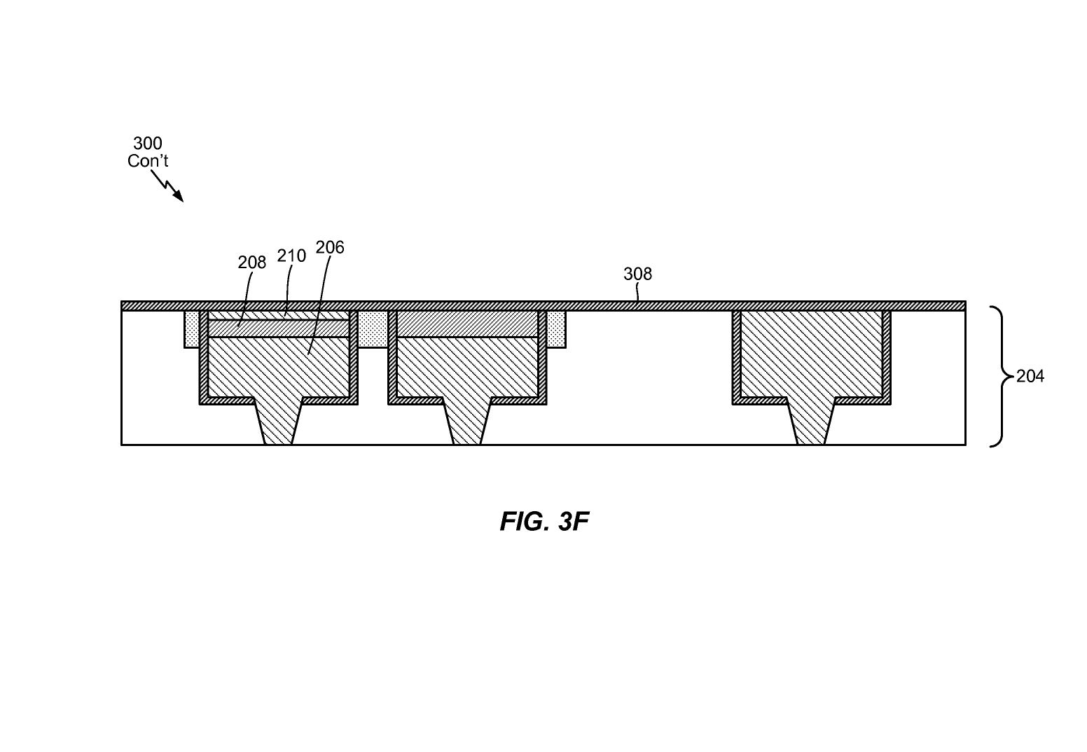

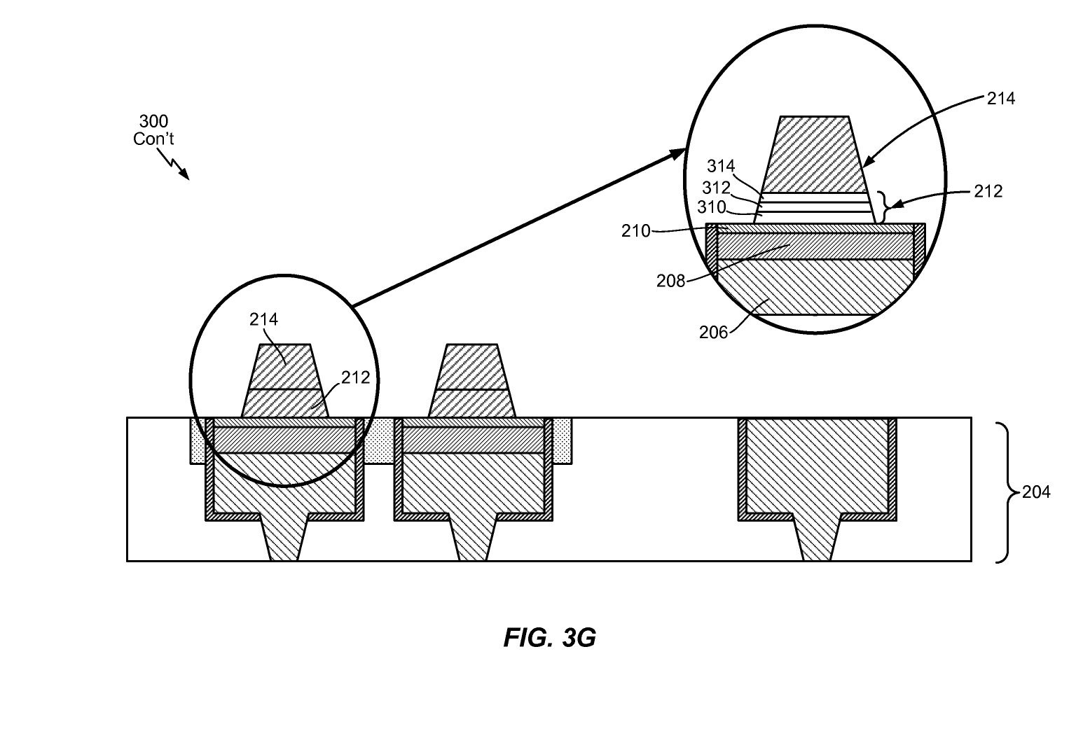

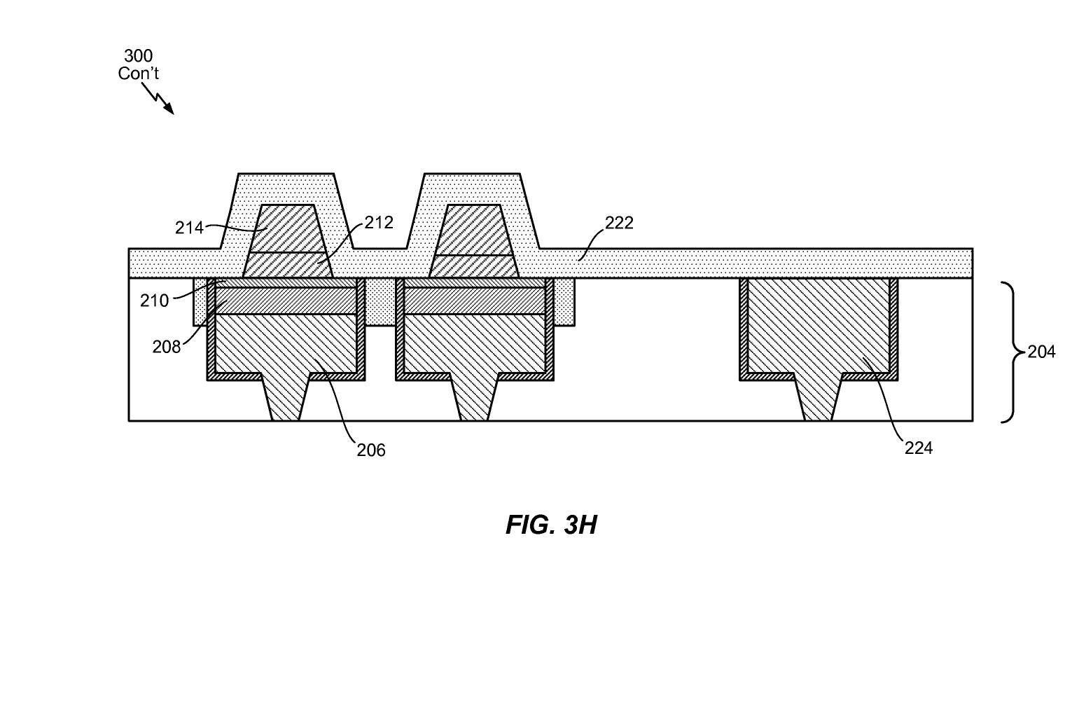

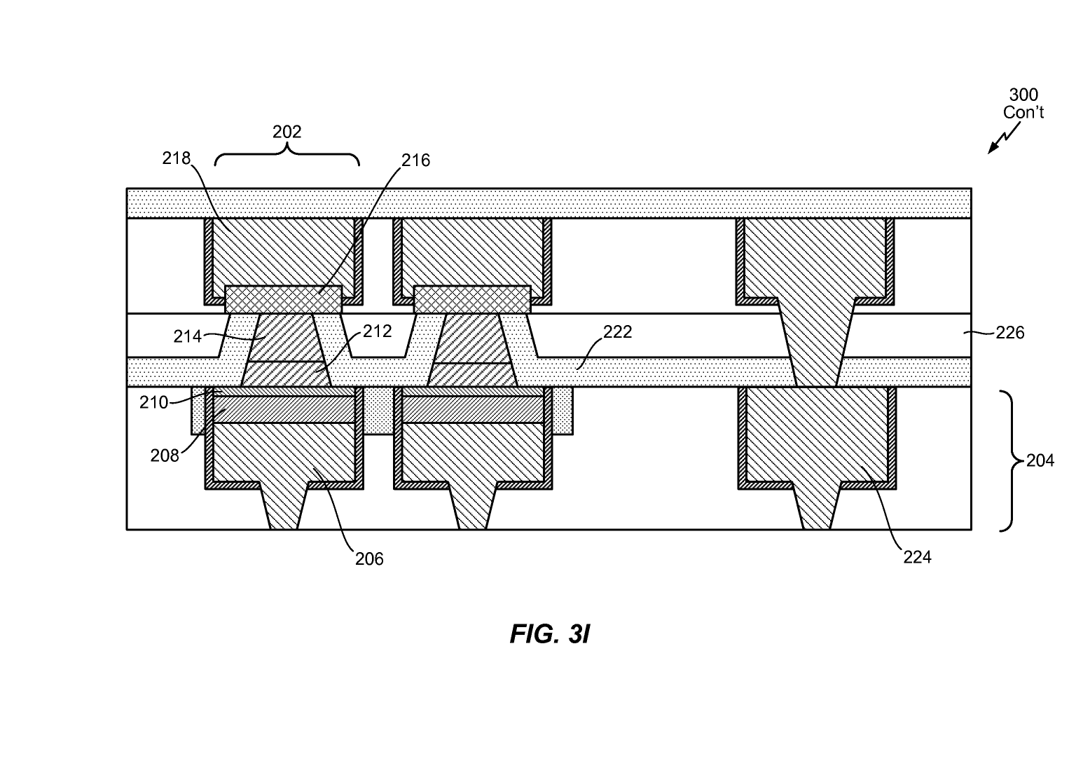

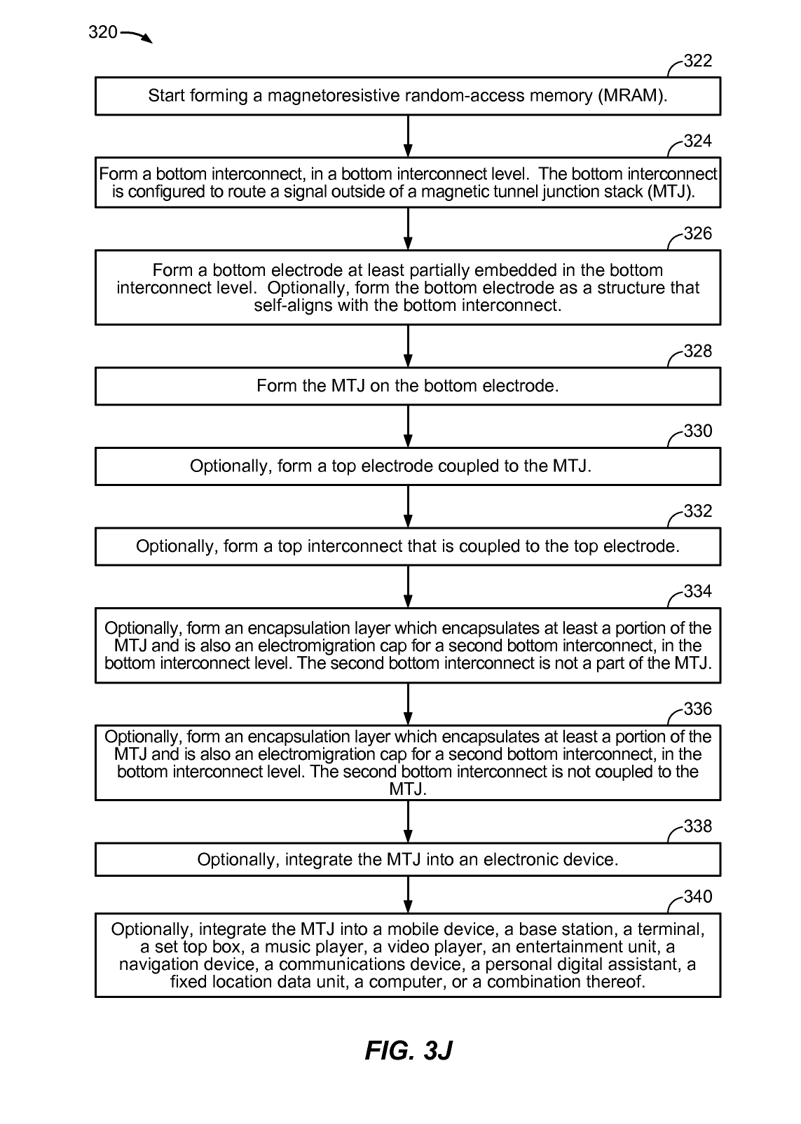

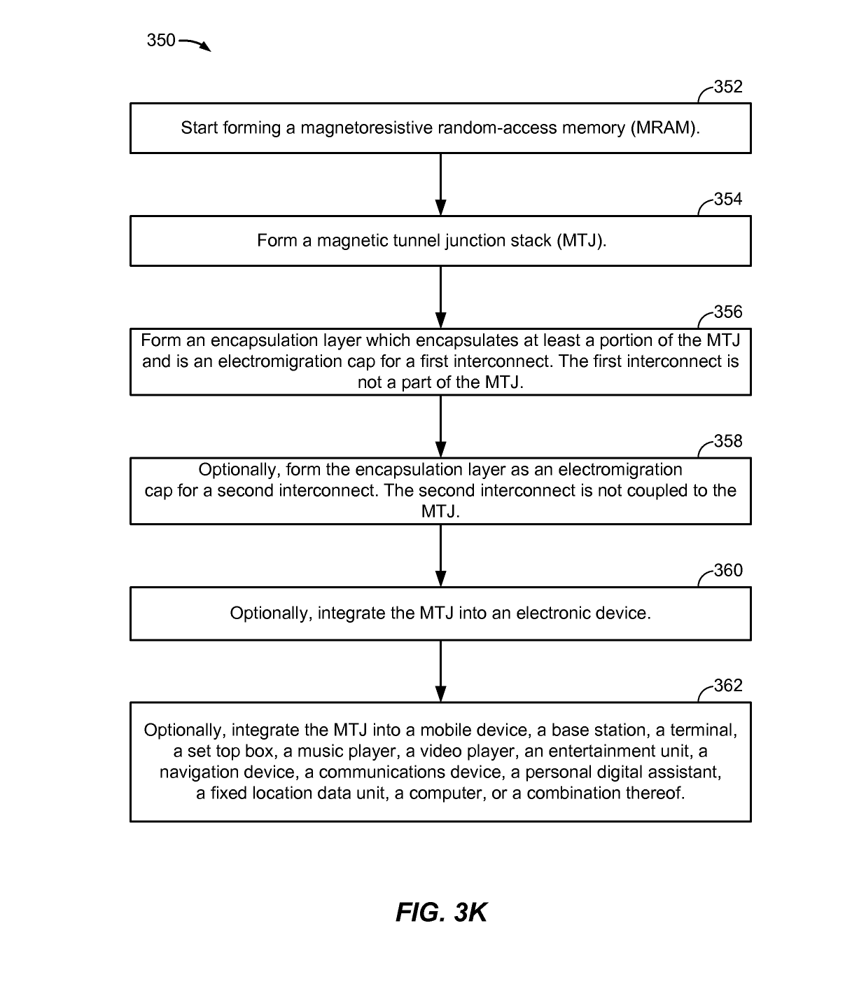

The circuit 200 also includes the MTJ stack 212. The MTJ stack 212 includes a reference layer (RL) (e.g., a pinned layer (PL)) on the BE 208, a barrier layer (BL) on the RL, and a free layer on the BL (these layers are shown in detail in FIG. 3G). The RL can be formed of at least one of Fe, Co, CoFe, or CoFeB. The BL can be formed of MgO. The FL can be formed of at least one of Fe, Co, CoFe, or CoFeB. A metal hardmask (MHM) layer 214 can be formed on the MTJ stack 212. A top electrode (TE) 216 can be formed on the MHM layer 214. The MHM layer 214 can be formed of Ta. A top interconnect 218 can be formed in electrical contact with the TE 216. In an example, the top interconnect 218 is formed of an electrically-conductive material, such as Ag, Al, Bi, Cu, In, Mo, Ni, Pb, Sn, Ta, Ti, W, polysilicon, or a combination thereof. The circuit 200 can also include a plasma-induced damage (PID) zone 220 limited to the MRAM region.

An encapsulation layer 222 can serve as an EM cap configured to mitigate effects of EM. The encapsulation layer 222 can be formed on a portion of the MTJ stack 212, the BE 208, the TE 216, or a combination thereof. In an example, the encapsulation layer 222 can also be an electromigration cap for a second bottom interconnect 224 in the bottom interconnect level 204. The second bottom interconnect 224 is formed of an electrically-conductive material, such as Ag, Al, Bi, Cu, In, Mo, Ni, Pb, Sn, Ta, Ti, W, polysilicon, or a combination thereof. The second bottom interconnect 224 is not a part of the memory cell 202. In another example, the second bottom interconnect 224 is not coupled to the memory cell 202. The second bottom interconnect can be configured to transfer a signal between integrated devices, configured to transfer a clock signal, configured to transfer power, configured to provide a ground, or a practicable combination thereof.

In a further example, the encapsulation layer 222 provides an encapsulation layer for a device other than the memory cell 202, while also being formed on at least a portion of the MTJ stack 212, the BE 208, the TE 216, or a combination thereof. The encapsulation layer 222 can be separated from other interconnect levels with a dielectric material 226 (e.g., an inter-level dielectric (ILD)).

FIGS. 3A-3I depict an exemplary method 300 for fabricating an exemplary MTJ structure, such as the MTJ stack 212, and other circuitry. Deposition of a material to form at least a portion of a structure described herein can be performed using deposition techniques such as physical vapor deposition (PVD, e.g., sputtering), plasma-enhanced chemical vapor deposition (PECVD), thermal chemical vapor deposition (thermal CVD), and/or spin-coating. Etching of a material to form at least a portion of a structure described herein can be performed using etching techniques such as plasma etching.

FIG. 3A depicts forming the first bottom interconnect 206 in the bottom interconnect level 204. The first bottom interconnect 206 can be formed of copper or another electrical conductor. After forming the first bottom interconnect 206, chemical-mechanical polishing (CMP) can be performed to planarize the first bottom interconnect 206, other structures in the bottom interconnect level 204, or combinations thereof.

FIG. 3B depicts depositing a hardmask (HM) layer 302, such as SiN. A photoresist (PR) 304 is formed on the HM layer 302, and lithography can be performed to remove a portion of the PR 304 (i.e., to define a cavity in the PR 304) in the MRAM portion of the circuit.

FIG. 3C depicts etching the HM layer 302 and removing the PR 304, thus forming an opening over a portion of the bottom interconnect 204. FIG. 3C further depicts selectively removing some metal, for example Cu, from the bottom interconnect 204 to create the cavity 306 in the bottom interconnect level 204. The cavity 306 is adjacent to the first bottom interconnect 206. At least a portion of the cavity 306 is defined by at least a portion of the first bottom interconnect 206. The cavity 306 can have at least one side wall substantially aligned with a side of the first bottom interconnect 206. FIG. 3C also depicts the PID zone 220.

FIG. 3D depicts forming the BE 208 in the cavity 306. The BE 208 can be formed of a conductive metal such as at least one of Co, Ta, or Ru. The BE 208 can be formed as a structure that self-aligns with the first bottom interconnect 206 as a result of being formed in the cavity 306. The BE 208 can be formed at least partially embedded in the bottom interconnect level 204. In an example, the BE 208 can be formed completely within the bottom interconnect level 204 (i.e., the BE 208 does not extend beyond the perimeter of the bottom interconnect level 204). Optionally, if the cavity 306 is too deep, then a portion of the cavity 306 can be filled with Cu by using electroless deposition (ELD). Alternatively, the portion of the cavity 306 can be filled with cobalt-tungsten-phosphide (CoWP) using ELD. In a non-limiting example, the cavity 306 is filled to a target depth of 5-10 nm below the surface of the bottom interconnect level 204. The self-aligning of the BE 208 reduces a number of patterns required to fabricate the memory cell 202, which also reduces fabrication costs and increases fabrication speed. Further, embedding the BE 208 in the bottom interconnect 204 eases meeting planarization tolerances when scaling height of the MTJ stack 212. Embedding the BE 208 also makes it easier to scale down the memory cell 202.

FIG. 3E depicts striping the HM layer 302 and depositing the base layer metal 210, such as TaN.

FIG. 3F depicts performing CMP to planarize the base layer metal 210 to form a smooth top surface suitable for MTJ layer deposition. Optionally, a thin conductive etch stop layer (ESL) 308 can be formed as a precursor step before performing an etch during the MTJ etch. The ESL 308 can be formed of Ta.

FIG. 3G depicts forming the MTJ stack 212 and the MHM 214 on the BE 208 (an optionally, on the ESL 308 on the BE 208). The MTJ stack 212 and the MHM 214 can be formed using material deposition followed by patterning, etching, and cleaning steps.

The MTJ stack 212 is in electrical contact with the BE 208. The MTJ stack 212 includes a reference layer (RL) 310 (e.g., a pinned layer (PL)) in electrical contact with the BE 208, a barrier layer (BL) 312 on the RL 310, and a free layer (FL) 314 on the BL 312. The RL 310 can be formed of at least one of Fe, Co, CoFe, or CoFeB. The BL 312 can be formed of MgO. The FL 314 can be formed of at least one of Fe, Co, CoFe, or CoFeB. Alternatively, the MTJ stack 212 is configured with the FL 314 in electrical contact with the BE 208, and the RL 310 is on top of the BL 312. In other words, the positions of the FL 314 and the RL 310 can be switched (relative to the positions depicted in FIG. 3G) so the FL 314 is closer to the BE 208 than the RL 310.

The MHM layer 214 is formed on the MTJ stack 212. The MHM layer 214 can be formed of Ta or TiN.

Optionally, the ESL 308 can be removed by etching the ESL 308 not covered by the MTJ stack 212.

FIG. 3H depicts depositing the encapsulation layer 222 to encapsulate a portion of the MTJ stack 212, the BE 208, the MHM 214, or a combination thereof. Optionally, the encapsulation layer 222 can also be an electromigration cap for the second bottom interconnect 224 in the bottom interconnect level 204. The second bottom interconnect 224 is not a part of the memory cell 202. Forming the encapsulation layer 222 on a circuit element that is not a part of the memory cell 202 can reduce a number of fabrication steps, which in turn reduces fabrication costs and reduces fabrication time.

In another example, the encapsulation layer 222 is an electromigration cap for the second bottom interconnect 224. The second bottom interconnect 224 is in at least a part of the bottom interconnect level 204. The second bottom interconnect 224 is not coupled to the memory cell 202.

In a further example, the encapsulation layer 222 provides an encapsulation layer for a device other than the memory cell 202, while also being formed on at least a portion of the MTJ stack 212, the BE 208, the MHM 214, or a combination thereof. The dielectric material 226 (for example, silicon oxide or a low-k insulator) can be formed on the encapsulation layer 222 to separate the encapsulation layer 222 from other interconnect levels.

FIG. 3I depicts performing CMP to planarize the dielectric material 226. Following planarization, the TE 216 is formed by a pattern, etch, deposition, and planarization process. Alternatively, the TE 216 can be formed by depositing the conductive material first, followed with patterning and etching. The top interconnect 218 can be formed in electrical contact with the TE 216 by using a patterning, etching, and deposition process. The top interconnect 218 can be formed of Cu using a dual-damascene process.

FIG. 3J depicts an exemplary method 320 for fabricating at least portions of a circuit, such as at least portions of the circuit 200.

In block 322, forming an MRAM is started. The MRAM can be formed at least in part using blocks 324 to 336.

In block 324, a bottom interconnect is formed in a bottom interconnect level, and is configured to route a signal outside of an MTJ stack.

In block 326, a bottom electrode is formed. The bottom electrode is at least partially embedded in the bottom interconnect level. Optionally, the bottom electrode is formed as a structure that self-aligns with the bottom interconnect.

In block 328, the MTJ stack is formed on the bottom electrode.

In optional block 330, an encapsulation layer is formed. The encapsulation layer encapsulates at least a portion of the MTJ stack and is also an electromigration cap for a second bottom interconnect in the bottom interconnect level. The second bottom interconnect is not a part of the MTJ stack. In another example, the second bottom interconnect is not a part of the MRAM.

In optional block 332, a top electrode is formed. The top electrode is coupled to the MTJ stack.

In optional block 334, a top copper interconnect is formed. The top copper interconnect is coupled to the top electrode.

In the optional block 336 an encapsulation layer is formed. The encapsulation layer encapsulates at least a portion of the MTJ stack and is also an electromigration cap for a second bottom interconnect in the bottom interconnect level. The second bottom interconnect is not coupled to the MTJ stack. In another example, the second bottom interconnect is not coupled to the MRAM.

In optional block 338, the MTJ stack is integrated into an electronic device.

In optional block 340, the MTJ stack is integrated into a mobile device, a base station, a terminal, a set top box, a music player, a video player, an entertainment unit, a navigation device, a communications device, a personal digital assistant, a fixed location data unit, a computer, or a combination thereof.

FIG. 3K depicts an exemplary method 350 for fabricating at least portions of a circuit, such as at least portions of the circuit 200.

In block 352, forming an MRAM is started. In a non-limiting example, the MRAM can be formed at least in part using blocks 354 to 358.

In block 354, a memory cell is formed. The memory cell is a part of the MRAM. The memory cell includes an MTJ stack.

In block 356, an encapsulation layer is formed. The encapsulation layer encapsulates at least a portion of the MTJ stack and is also an electromigration cap for a first interconnect (for example, a first interconnect in a bottom interconnect level). In an example, the first interconnect is not a part of the MTJ stack. In another example, the first interconnect is not a part of the memory cell. In a further example, the first interconnect is not a part of the MRAM.

In optional block 358, the encapsulation layer is also an electromigration cap for a second interconnect (for example, a second interconnect in the bottom interconnect level). The second interconnect is not coupled to the MTJ stack. In another example, the second interconnect is not coupled to the memory cell. In a further example, the second interconnect is not coupled to the MRAM.

In the optional block 360, the MTJ stack is integrated into an electronic device.

In optional block 362, the MTJ stack is integrated into a mobile device, a base station, a terminal, a set top box, a music player, a video player, an entertainment unit, a navigation device, a communications device, a personal digital assistant, a fixed location data unit, a computer, or a combination thereof.

The blocks described herein are not limiting of the examples. The blocks can be combined, the order can be rearranged, or both, as is practicable.

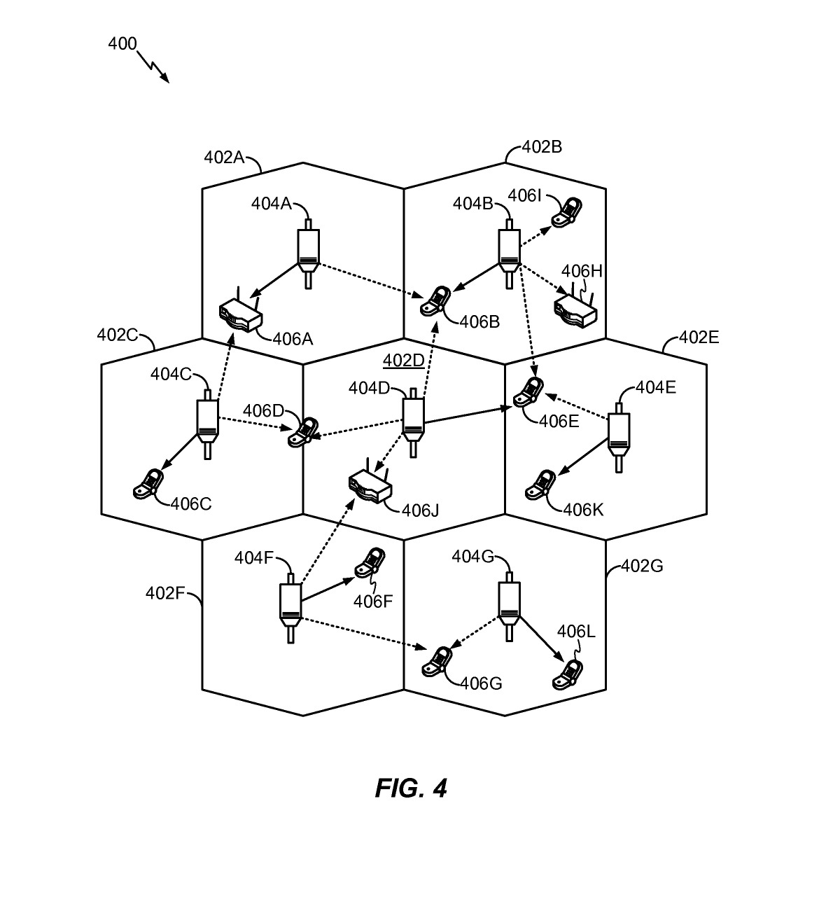

FIG. 4 depicts an exemplary wireless communication network 400. The wireless communication network 400 is configured to support multiple access communication between multiple users. As shown, the wireless communication network 400 can be divided into one or more cells 402A-402G. One or more access points 404A-404G provide communication coverage in corresponding cells 402A-402G. The access points 404A-404G can interact with at least one user device in a plurality of user devices 406A-406L. At least a portion of the apparatus disclosed herein (e.g., the circuit 200) can be a part of at least one of the access points 404A-404G. At least a portion of the apparatus disclosed herein can be a part of at least one of the user devices 406A-406L. In an example, the circuit 200 can be integrated into at least one device in the wireless communication network 400, such as the access points 404A-404G, the user devices 406A-406L, or a combination thereof.

Each user device 406A-406L can communicate with one or more of the access points 404A-404G via a downlink (DL) and/or an uplink (UL). In general, a DL is a communication link from an access point to a user device, while an UL is a communication link from a user device to an access point. The access points 404A-404G can be coupled to each other and/or other network equipment via wired or wireless interfaces, allowing the access points 404A-404G to communicate with each other and/or the other network equipment. Accordingly, each user device 406A-406L can also communicate with another user device 406A-406L via one or more of the access points 404A-404G. For example, the user device 406J can communicate with the user device 406H in the following manner: the user device 406J can communicate with the access point 404D, the access point 404D can communicate with the access point 404B, and the access point 404B can communicate with the user device 406H, enabling communication to be established between the user device 406J and the user device 406H.

A wireless communication network, such as the wireless communication network 400, can provide service over a geographic region ranging from small to large. For example, the cells 402A-402G can cover a few blocks within a neighborhood or several square miles in a rural environment. In some systems, each of the cells 402A-402G can be further divided into one or more sectors (not shown in FIG. 4). In addition, the access points 404A-404G can provide the user devices 406A-406L, within their respective coverage areas (i.e., respective cells 402A-402G), with access to other communication networks, such as at least one of the Internet, a cellular network, a private network, and the like. In the example shown in FIG. 4, the user devices 406A, 406H, and 406J comprise routers, while the user devices 406B-406G, 406I, 406K, and 406L comprise mobile devices. However, each of the user devices 406A-406L can comprise any suitable communication device.

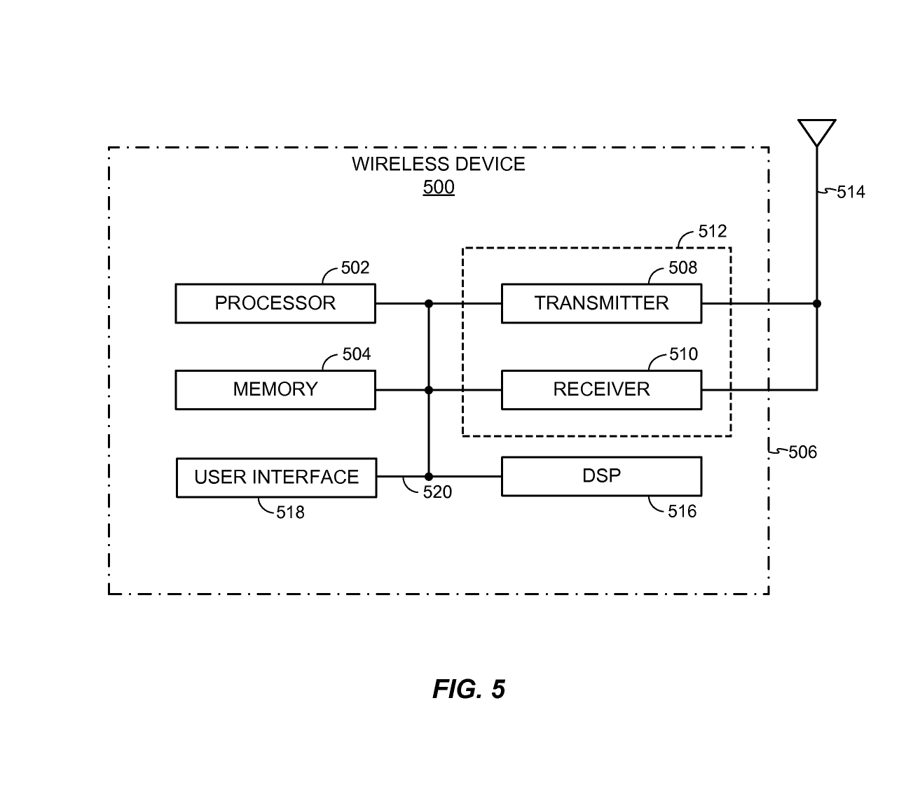

FIG. 5 depicts an exemplary functional block diagram of an exemplary user device 500 corresponding to at least one of the user devices 406A-406L. FIG. 5 also depicts different components that can be a part of the user device 500. The user device 500 is an example of a device that can be configured to include at least a portion of the apparatus described herein. In an example, at least a portion of the circuit 200 can be integrated into the user device 500.

The user device 500 can include a processor 502 configured to control operation of the user device 500, including performing at least a part of a method described herein. The processor 502 can also be referred to as a central processing unit (CPU), a special-purpose processor, or both. A memory 504 can include at least one of a read-only memory (ROM) or a random access memory (RAM), and provides at least one of instructions or data to the processor 502. The processor 502 can perform logical and arithmetic operations based on processor-executable instructions stored within the memory 504. In an example, the circuit 200 can be an integral part of the memory 504. The processor 502 can comprise or be a component of a processing system implemented with one or more processors. The one or more processors can be implemented with a microprocessor, a microcontroller, a digital signal processor (DSP), a field programmable gate array (FPGA), a programmable logic device (PLD), an application-specific integrated circuit (ASIC), a controller, a state machine, gated logic, a discrete hardware component, a dedicated hardware finite state machine, any other suitable entity that can at least one of manipulate information (e.g., calculating, logical operations, and the like), control another device, the like, or a combination thereof. The processing system can also include a non-transitory machine-readable medium (e.g., the memory 504) that stores software. Software can mean any type of instructions, whether referred to as at least one of software, firmware, middleware, microcode, hardware description language, the like, or a combination thereof. Instructions can include code (e.g., in source code format, binary code format, executable code format, or any other suitable code format). The instructions are processor-executable and are configured to perform at least a portion of a function described hereby. The instructions, when executed by the processor 502, can transform the processor 502 into a special-purpose processor.

The user device 500 can also include a housing 506. The user device 500 can also include a transmitter 508, a receiver 510, or a combination thereof, that are configured to communicate information between the user device 500 and a remote location. The transmitter 508 and the receiver 510 can be combined into a transceiver 512. An antenna 514 can be attached to the housing 506. The antenna 514 can be electrically coupled to the transmitter 508, the receiver 510, or a combination thereof. The user device 500 can also include (not shown in FIG. 5) multiple transmitters, multiple receivers, multiple transceivers, and/or multiple antennas.

The user device 500 can further comprise an optional digital signal processor (DSP) 516 configured to process information. The user device 500 can also further comprise a user interface 518. The user interface 518 can comprise a keypad, a microphone, a speaker, a display, the like, or a combination thereof. The user interface 518 can include a component that at least one of conveys information to a user of the user device 500 and receives information from the user of the user device 500.

The components of the user device 500 can be coupled together by a bus system 520. The bus system 520 can include a data bus, a power bus, a control signal bus, a status signal bus, the like, or a combination thereof. The components of the user device 500 can be coupled together to communicate with each other using a different suitable mechanism.

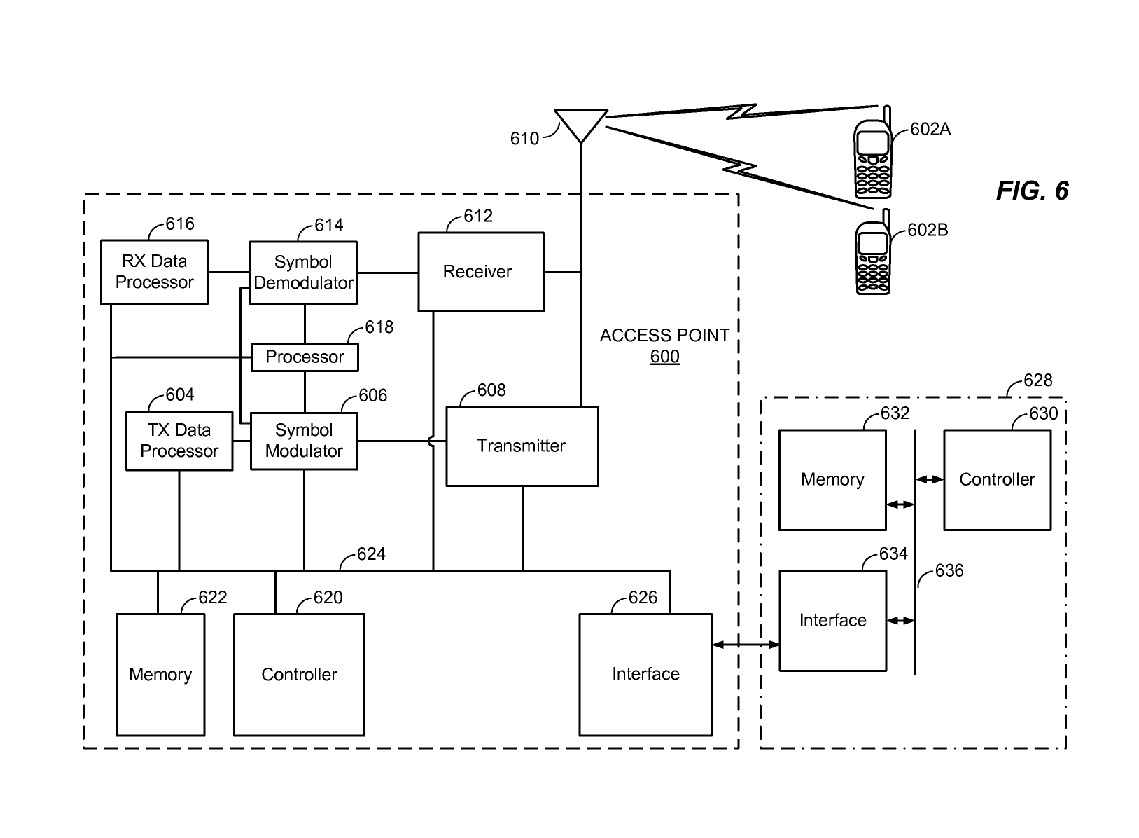

FIG. 6 depicts an exemplary access point 600. The access point 600 can correspond to any of the access points 404A-404G. In an example, at least a portion of the circuit 200 can be integrated into the access point 600.

As shown, the access point 600 includes a transmit (TX) data processor 604, a symbol modulator 606, a transmitter unit (TMTR) 608, an antenna 610, a receiver unit (RCVR) 612, a symbol demodulator 614, a receive (RX) data processor 616, and a configuration information processor 618, each performing an operation associated with communicating with one or more user devices 602A-602B. The user devices 602A-602B can correspond to at least one user device in a plurality of user devices 406A-406L. The access point 600 can also include a controller 620 and a memory 622 configured to store related data or instructions. In an example, at least a portion of the circuit 200 can be an integral part of the memory 622. Together, via a bus system 624, these units can perform special-purpose processing in accordance with the appropriate radio communication technology, as well as other functions for the access point 600.

The controller 620 is configured to control operation of the access point 600. The controller 620 can also be referred to as a CPU, a special-purpose processor, or both. The memory 622 can include at least one of a ROM and a RAM, and provides instructions and data to the controller 620. The controller 620 can perform logical and arithmetic operations based on program instructions stored within the memory 622. The instructions in the memory 622 can be executable to implement at least a part of a function described herein. The controller 620 can comprise or be a component of a processing system implemented with one or more processors. The one or more processors can be implemented with a microprocessor, a microcontroller, a DSP, an FPGA, a PLD, an ASIC, a controller, a state machine, gated logic, a discrete hardware component, a dedicated hardware finite state machine, and any other suitable entity that can at least one of manipulate information (e.g., calculating, logical operations, and the like) and control another device, or a combination thereof. The processing system can also include a non-transitory machine-readable medium (e.g., the memory 622) that stores software. Software can mean any type of instructions, whether referred to as at least one of software, firmware, middleware, microcode, hardware description language, and the like. Instructions can include code (e.g., in source code format, binary code format, executable code format, or any other suitable code format). The instructions are processor-executable and are configured to perform at least a portion of a method described hereby. The instructions, when executed by the controller 620, can transform the controller 620 into a special-purpose processor that causes the controller 620 to perform at least a part of a function described hereby.

The components of the access point 600 can be coupled together by the bus system 624. The bus system 624 can include at least one of a data bus, a power bus, a control signal bus, and a status signal bus. The components of the access point 600 can be coupled together to accept and/or provide inputs to each other using a different suitable mechanism. The access point 600 can include an interface 626 configured to couple at least one of the constituent components of the access point 600 to an optional computer 628.

FIG. 6 also depicts the optional computer 628. In an example, the computer 628 includes a controller 630, a memory 632, an interface 634, and a bus system 636. In an example, at least a portion of the circuit 200 can be integrated into the computer 628, such as being an integral part of the memory 632. In an example, the computer 628 is not coupled to the access point 600.

Further, those of skill in the art will appreciate that the exemplary logical blocks, modules, circuits, and steps described in the examples disclosed herein can be implemented as electronic hardware, computer software, or combinations of both, as practicable. To clearly illustrate this interchangeability of hardware and software, exemplary components, blocks, modules, circuits, and steps have been described herein generally in terms of their functionality. Whether such functionality is implemented as hardware or software depends upon the particular application and design constraints imposed on an overall system. Skilled artisans can implement the described functionality in different ways for each particular application, but such implementation decisions should not be interpreted as causing a departure from the scope of the present disclosure.

At least a portion of the methods, sequences, and/or algorithms described in connection with the examples disclosed herein can be embodied directly in hardware, in software executed by a processor (e.g., a processor described hereby), or in a combination of the two. In an example, a processor includes multiple discrete hardware components. A software module can reside in a storage medium (e.g., a memory device), such as a RAM, a flash memory, a ROM, an erasable programmable read-only memory (EPROM), an electrically erasable programmable read-only memory (EEPROM), a register, a hard disk, a removable disk, a compact disc read-only memory (CD-ROM), a Subscriber Identity Module (SIM) card, a Universal Subscriber Identity Module (USIM) card, and/or any other form of storage medium. An exemplary storage medium (e.g., a memory device) can be coupled to the processor such that the processor can read information from, and/or write information to, the storage medium. In an example, the storage medium can be integral with the processor.

Further, examples provided hereby are described in terms of sequences of actions to be performed by, for example, at least one element of a computing device. The actions described herein can be performed by a specific circuit (e.g., an ASIC), by program instructions being executed by one or more processors, or by a combination of both. Additionally, a sequence of actions described herein can be entirely within any form of computer-readable storage medium having stored therein a corresponding set of computer instructions that, upon execution, would cause an associated processor (such as a special-purpose processor) to perform at least a portion of a function described herein. Thus, examples may be in a number of different forms, all of which have been contemplated to be within the scope of the disclosure. In addition, for each of the examples described herein, a corresponding electrical circuit of any such examples may be described herein as, for example, “logic configured to” perform a described action.

In an example, when a general-purpose computer (e.g., a processor) is configured to perform at least a portion of a method described herein, then the general-purpose computer becomes a non-generic special-purpose computer. The non-generic special-purpose computer is not a general-purpose computer. In an example, loading a general-purpose computer with special programming can cause the general-purpose computer to be configured to perform at least a portion of a method described herein. In an example, a combination of at least two related method steps disclosed herein forms a sufficient algorithm. In an example, a sufficient algorithm constitutes special programming. In an example, any software that can cause a computer (e.g., a general-purpose computer, a special-purpose computer, etc.) to be configured to perform at least one function, feature, step algorithm, block, or combination thereof, as disclosed herein, constitutes special programming.

The disclosed devices and methods can be designed and can be configured into a computer-executable file (e.g., a lithographic device-executable file) in a Graphic Database System Two (GDSII) compatible format, an Open Artwork System Interchange Standard (OASIS) compatible format, a GERBER (e.g., RS-274D, RS-274X, etc.) compatible format, or a combination thereof. The computer-executable file can be stored on a non-transitory (i.e., a non-transient) computer-readable medium. The computer-executable file can be provided to a fabrication handler who fabricates with a lithographic device, based on the file, an integrated device. Deposition of a material to form at least a portion of a structure described herein can be performed using deposition techniques such as physical vapor deposition (PVD, e.g., sputtering), plasma-enhanced chemical vapor deposition (PECVD), thermal chemical vapor deposition (thermal CVD), spin-coating, the like, or a combination thereof. Etching of a material to form at least a portion of a structure described herein can be performed using etching techniques such as plasma etching. In an example, the integrated device is on a semiconductor wafer. The semiconductor wafer can be cut into a semiconductor die and packaged into a semiconductor chip. The semiconductor chip can be employed in a device described herein (e.g., a mobile device, an access device, and/or the like).

At least one example provided hereby can include a non-transitory (i.e., a non-transient) machine-readable medium and/or a non-transitory (i.e., a non-transient) computer-readable medium storing processor-executable instructions configured to cause a processor (e.g., a special-purpose processor) to transform the processor and any other cooperating devices into a machine (e.g., a special-purpose processor) configured to perform at least a part of a function described hereby and/or a method described hereby. Performing at least a part of a function described hereby can include initiating at least a part of a function described hereby. A non-transitory (i.e., a non-transient) machine-readable medium specifically excludes a transitory propagating signal. Further, at least one embodiment of the invention can include a computer-readable medium embodying at least a part of a method described herein. Accordingly, any means for performing the functions described herein are included in at least one embodiment of the invention. A non-transitory (i.e., a non-transient) machine-readable medium specifically excludes a transitory propagating signal.

Nothing stated or depicted in this application is intended to dedicate any component, step, block, feature, object, benefit, advantage, or equivalent to the public, regardless of whether the component, step, block, feature, object, benefit, advantage, or the equivalent is recited in the claims.

While this disclosure describes examples, changes and modifications can be made to the examples disclosed herein without departing from the scope defined by the appended claims. The present disclosure is not intended to be limited to the specifically disclosed examples alone.

1. A circuit, comprising:
a magnetoresistive random-access memory (MRAM), including:
a bottom interconnect in a bottom interconnect level, wherein the bottom interconnect is configured to route a signal outside of a magnetic tunnel junction (MTJ) stack; and
a bottom electrode on the bottom interconnect such that the bottom electrode is at least partially embedded in the bottom interconnect level,
wherein the MTJ stack is formed on the bottom electrode, and
wherein a top surface of the bottom interconnect in the bottom interconnect level is below a top of the bottom interconnect level.

2. The circuit of claim 1, further comprising:
a top electrode electrically coupled to the MTJ stack; and
a top copper interconnect electrically coupled to the top electrode.

3. The circuit of claim 1, further comprising an encapsulation layer configured to encapsulate at least a portion of the MTJ stack including at least a portion of each of a reference layer (RL), a barrier layer (BL), and a free layer (FL) of the MTJ stack,
wherein the encapsulation layer is an electromigration cap for a second bottom interconnect, in the bottom interconnect level, and the second bottom interconnect is not a part of the MTJ stack.

4. The circuit of claim 1, further comprising an encapsulation layer configured to encapsulate at least a portion of the MTJ stack including at least a portion of each of a reference layer (RL), a barrier layer (BL), and a free layer (FL) of the MTJ stack,
wherein the encapsulation layer is an electromigration cap for a second bottom interconnect, in the bottom interconnect level, and the second bottom interconnect is not electrically coupled to the MTJ stack.

5. The circuit of claim 1, wherein the bottom electrode is self-aligned to the bottom interconnect.

6. The circuit of claim 1, wherein the MRAM is a spin-transfer torque-MRAM.

7. The circuit of claim 1, wherein the bottom electrode is completely embedded in the bottom interconnect level.

8. The circuit of claim 1, further comprising an electronic device, wherein the MTJ stack is a constituent part of the electronic device.

9. The circuit of claim 1, further comprising a mobile device, a base station, a terminal, a set top box, a music player, a video player, an entertainment unit, a navigation device, a communications device, a personal digital assistant, a fixed location data unit, a computer, or a combination thereof, with which the MTJ stack is a constituent part.

10. A method for fabricating a circuit, comprising:
forming a magnetoresistive random-access memory, including:
forming a bottom interconnect in a bottom interconnect level, wherein the bottom interconnect is configured to route a signal outside of a magnetic tunnel junction (MTJ) stack;
forming a bottom electrode on the bottom interconnect such that the bottom electrode is at least partially embedded in the bottom interconnect level; and
forming the MTJ stack on the bottom electrode,
wherein forming the bottom interconnect comprises forming the bottom interconnect such that a top surface of the bottom interconnect in the bottom interconnect level is below a top of the bottom interconnect level.

11. The method of claim 10, further comprising:
forming a top electrode electrically coupled to the MTJ stack; and
forming a top copper interconnect electrically coupled to the top electrode.

12. The method of claim 10, further comprising forming an encapsulation layer configured to encapsulate at least a portion of the MTJ stack including at least a portion of each of a reference layer (RL), a barrier layer (BL), and a free layer (FL) of the MTJ stack,
wherein the encapsulation layer is an electromigration cap for a second bottom interconnect, in the bottom interconnect level, and the second bottom interconnect is not a part of the MTJ stack.

13. The method of claim 10, further comprising forming an encapsulation layer configured to encapsulate at least a portion of the MTJ stack including at least a portion of each of a reference layer (RL), a barrier layer (BL), and a free layer (FL) of the MTJ stack,
wherein the encapsulation layer is an electromigration cap for a second bottom interconnect, in the bottom interconnect level, and the second bottom interconnect is not electrically coupled to the MTJ stack.

14. The method of claim 10, further comprising forming the bottom electrode as self-aligned with the bottom interconnect.

15. The method of claim 10, further comprising forming the MRAM as a spin-transfer torque-MRAM.

16. The method of claim 10, further comprising forming the bottom electrode as completely embedded in the bottom interconnect level.

17. The method of claim 10, further comprising an electronic device, wherein the MTJ stack is a constituent part of the electronic device.

18. The method of claim 10, further comprising integrating the MTJ stack into a mobile device, a base station, a terminal, a set top box, a music player, a video player, an entertainment unit, a navigation device, a communications device, a personal digital assistant, a fixed location data unit, a computer, or a combination thereof.

19. A non-transitory computer-readable medium, comprising:
fabrication device-executable instructions stored thereon configured to cause a fabrication device to fabricate at least a part of an integrated circuit including:
a magnetoresistive random-access memory (MRAM), including:
a bottom interconnect in a bottom interconnect level, wherein the bottom interconnect is configured to route a signal outside of a magnetic tunnel junction (MTJ) stack; and
a bottom electrode on the bottom interconnect such that the bottom electrode is at least partially embedded in the bottom interconnect level,
wherein the MTJ stack is formed on the bottom electrode, and
wherein a top surface of the bottom interconnect in the bottom interconnect level is below a top of the bottom interconnect level.

20. The non-transitory computer-readable medium of claim 19, further comprising fabrication device-executable instructions stored thereon configured to cause the fabrication device to fabricate:
a top electrode electrically coupled to the MTJ stack; and
a top copper interconnect electrically coupled to the top electrode.

21. The non-transitory computer-readable medium of claim 19, further comprising fabrication device-executable instructions stored thereon configured to cause the fabrication device to fabricate an encapsulation layer configured to encapsulate at least a portion of the MTJ stack including at least a portion of each of a reference layer (RL), a barrier layer (BL), and a free layer (FL) of the MTJ stack,
wherein the encapsulation layer is an electromigration cap for a second bottom interconnect, in the bottom interconnect level, and the second bottom interconnect is not a part of the MTJ stack.

22. The non-transitory computer-readable medium of claim 19, further comprising fabrication device-executable instructions stored thereon configured to cause the fabrication device to fabricate an encapsulation layer configured to encapsulate at least a portion of the MTJ stack including at least a portion of each of a reference layer (RL), a barrier layer (BL), and a free layer (FL) of the MTJ stack,
wherein the encapsulation layer is an electromigration cap for a second bottom interconnect, in the bottom interconnect level, and the second bottom interconnect is not electrically coupled to the MTJ stack.

23. The non-transitory computer-readable medium of claim 19, further comprising fabrication device-executable instructions stored thereon configured to cause the fabrication device to fabricate the bottom electrode as self-aligned with the bottom interconnect.

24. The non-transitory computer-readable medium of claim 19, further comprising fabrication device-executable instructions stored thereon configured to cause the fabrication device to fabricate a spin-transfer torque-MRAM as the MRAM.

25. The non-transitory computer-readable medium of claim 19, further comprising fabrication device-executable instructions stored thereon configured to cause the fabrication device to fabricate the bottom electrode as completely embedded in the bottom interconnect level.

26. The non-transitory computer-readable medium of claim 19, further comprising fabrication device-executable instructions stored thereon configured to cause the fabrication device to fabricate an electronic device, wherein the MTJ stack is a constituent part of the electronic device.

27. A circuit, comprising:
a magnetoresistive random-access memory, including:
a magnetic tunnel junction (MTJ) stack; and
an encapsulation layer encapsulating at least a portion of the MTJ stack including at least a portion of each of a reference layer (RL), a barrier layer (BL), and a free layer (FL) of the MTJ stack,
wherein the encapsulation layer is an electromigration cap for an interconnect, and the interconnect not a part of the MTJ stack.

28. The circuit of claim 27, wherein the interconnect is not electrically coupled to the MTJ stack.

29. The circuit of claim 27, further comprising an electronic device, wherein the MTJ stack is a constituent part of the electronic device.

30. The circuit of claim 27, further comprising a mobile device, a base station, a terminal, a set top box, a music player, a video player, an entertainment unit, a navigation device, a communications device, a personal digital assistant, a fixed location data unit, a computer, or a combination thereof, with which the MTJ stack is a constituent part.

31. A method for fabricating a circuit, comprising:
forming a magnetoresistive random-access memory, including:
forming a magnetic tunnel junction (MTJ) stack; and
forming an encapsulation layer encapsulating at least a portion of the MTJ stack including at least a portion of each of a reference layer (RL), a barrier layer (BL), and a free layer (FL) of the MTJ stack,
wherein the encapsulation layer is an electromigration cap for an interconnect, and the interconnect not a part of the MTJ stack.

32. The method of claim 31, wherein the interconnect is not electrically coupled to the MTJ stack.

33. The method of claim 31, further comprising integrating the MTJ stack into an electronic device.

34. The method of claim 31, further comprising integrating the MTJ stack into a mobile device, a base station, a terminal, a set top box, a music player, a video player, an entertainment unit, a navigation device, a communications device, a personal digital assistant, a fixed location data unit, a computer, or a combination thereof.

35. A non-transitory computer-readable medium, comprising:
fabrication device-executable instructions stored thereon configured to cause a fabrication device to fabricate at least a part of an integrated circuit including:
a magnetoresistive random-access memory, including:
a magnetic tunnel junction (MTJ) stack; and
an encapsulation layer encapsulating at least a portion of the MTJ stack including at least a portion of each of a reference layer (RL), a barrier layer (BL), and a free layer (FL) of the MTJ stack,
wherein the encapsulation layer is an electromigration cap for an interconnect, and the interconnect not a part of the MTJ stack.

36. The non-transitory computer-readable medium of claim 35, wherein the interconnect is not electrically coupled to the MTJ stack.

37. The non-transitory computer-readable medium of claim 35, further comprising fabrication device-executable instructions stored thereon configured to cause the fabrication device to fabricate an electronic device, wherein the MTJ stack is a constituent part of the electronic device.

38. The circuit of claim 1,
wherein the bottom electrode is completely embedded in the bottom interconnect level such that a top surface of the bottom electrode is below a top of the bottom interconnect level, and
wherein the circuit further comprises a base layer metal embedded in the bottom interconnect level vertically in between the MTJ stack and the bottom electrode such that a top surface of the base layer metal and the top of the bottom interconnect level are planar.

39. The method of claim 10,
wherein forming the bottom electrode comprises forming the bottom electrode on the bottom interconnect so as to be completely embedded in the bottom interconnect level such that a top surface of the bottom electrode is below a top of the bottom interconnect level, and
wherein the method further comprises forming a base layer metal embedded in the bottom interconnect level vertically in between the MTJ stack and the bottom electrode such that a top surface of the base layer metal and the top of the bottom interconnect level are planar.

40. The non-transitory computer-readable medium of claim 19,
wherein the fabrication device-executable instructions stored thereon causes the fabrication device to fabricate the bottom electrode on the bottom interconnect so as to be completely embedded in the bottom interconnect level such that a top surface of the bottom electrode is below a top of the bottom interconnect level, and
wherein the non-transitory computer-readable medium further comprises fabrication device-executable instructions stored thereon configured to cause the fabrication device to fabricate a base layer metal embedded in the bottom interconnect level vertically in between the MTJ stack and the bottom electrode such that a top surface of the base layer metal and the top of the bottom interconnect level are planar.

41. The circuit of claim 27, wherein the encapsulation layer is electrically insulative.

42. The method of claim 31, wherein forming the encapsulation layer forming the encapsulation layer that is electrically insulative.

43. The non-transitory computer-readable medium of claim 35, wherein the fabrication device-executable instructions stored thereon causes the fabrication device to fabricate the encapsulation layer that is electrically insulative.
